(19) United States
(12) Patent Application Publication
(10) Pub. No.: US 2021/0311126 A1
(43) Pub. Date: Oct. 7, 2021

(54) METHOD AND DEVICE FOR MEASURING THE HEALTH OF A MULTICELL AUTOMOTIVE BATTERY

(71) Applicant: STRA, S.A., Coimbra (PT)

(72) Inventors: Humberto Jorge MARTINS RODRIGUES, Coimbra (PT); João Miguel GOMES BENTO DE SOUSA, Coimbra (PT); Mariana Patrícia PROENÇA MONTEIRO, Coimbra (PT)

(21) Appl. No.: 17/260,182

(22) PCT Filed: Jul. 17, 2019
(86) PCT No.: PCT/IB2019/056109

§ 371 Date: Jan. 13, 2021

(30) Foreign Application Priority Data
Jul. 17, 2018 (PT) 110857

(51) Int. Cl. G01R 31/389; G01R 31/396; G01R 31/388

(52) U.S. Cl. CPC G01R 31/389; G01R 31/388; G01R 31/396

(57) ABSTRACT

A method for measuring the internal resistance of a multicell automotive battery comprising a plurality of battery cells in series, comprising: scanning the plurality of battery cells to measure their respective voltages until the battery current is stable for a full cell scan with a current value; recording said current value and scanned battery cell voltages; using the recorded current value and battery cell voltages to calculate the internal resistance of each battery cell. Optionally, scanning the plurality of battery cells for measuring their respective voltage until the battery current has been stable for a full cell scan with a second current value which is different from said first current value; recording said second current value and second scanned battery cell voltages; using the recorded first current value, first battery cell voltages, second current value, and second battery cell voltages to calculate the internal resistance of each battery cell.

### TECHNICAL FIELD

The present disclosure relates to a method and device for measuring the health of a multicell automotive battery, in particular a method and device for measuring the internal resistance of a multicell automotive battery.

### BACKGROUND

The main purpose of a battery is to store and provide electrical energy. They have different sizes, capacities and chemistries that are suitable for different target applications. These devices are made of three main components, first there is the anode, normally marked as the negative side on the battery, where the electrons flow out into the positive side, the cathode. The cathode is present on the opposite side of the anode and in the middle, we have isolating material, the electrolyte, usually a liquid gel that reacts with the anode and cathode.

When batteries are connected to external load a chemical reaction called oxidation happens, from the interaction of the anode with the electrolyte, producing electrons which are used in another simultaneous reaction between the electrolyte and cathode called reduction. This transaction, through electrochemical reactions, of electrons from de negative to the positive pole creates an electrical current. Batteries are divided into primary and secondary batteries, which are basically non-rechargeable and rechargeable, respectively. The difference between them is the reversibility of the chemical reaction that allows them to be reused.

A cell can be represented electrically by an ideal cell and an equivalent series resistor. This intrinsic parameter of the battery is not only dependent of its chemistry but also is an indicator of its performance.

Batteries are groups of cells built with complex process and expensive materials, each one unique owing to the method of production. Batteries are formed by large arrays of cells in series where one cell will limit the whole battery performance. It is a commonly known fact that the parameter internal resistance increases as the cell degrades, and this results in a lower cell capacity as well as a lower C-rate.

C-rate has to do with charge and discharge capability, meaning that a battery rated for a xC may be charged or discharged at a maximum rate of x its capacity in A/h. This correlation is non-linear at higher discharge rates.

Batteries have been widely used in automotive industry, which requires to use several cells per pack and this requires to monitor hundreds of individual cells. As a consequence, service and maintenance are crucial to maintain proper operation under severe conditions found on vehicles. However, this task also needs to stop the car for maintenance periodically having skilled service and downtime costs. Vehicle performance is influenced by a faulty cell and an early check is essential to act timely and thus avoiding complete failure of the vehicle and road side assistance.

The State of Charge (SoC) of a battery is the parameter that gives the indication of how much energy the battery still holds. Combined with SoC, the State of Health (SoH) is an indicator of how much the pack is degraded.

One of the simplest method to measure the state-of-charge SoC of a battery is measure its no-load voltage. This method relates the voltage per cell to a known manufacture defined function of voltage-SoC. This method is not usable on Lithium based cells due their relatively flat voltage discharge curve.

The capacity of a battery is a more truthful indicator of its health. This measurement is not so simplistic it looks due to the need a complete charge-discharge cycle, applying a coulomb counting method to integrate the current during the charge and discharge. This is also a method that has errors from the current sensors and is strongly influenced by the temperature, which will cause wrong estimations of SoC.

Nowadays, lithium based batteries have the greatest energy density compared with other chemistries and are the most commonly used in automotive applications and the monitoring and estimation methods discussed are focused on this technology. Real-time monitoring is accomplished by the Battery Management System (BMS) that monitors the voltage at individual cell along with the current and temperature of the pack. Both sensors provide a reasonable estimation of SoC.

These facts are disclosed in order to illustrate the technical problem addressed by the present disclosure.

### GENERAL DESCRIPTION

The present disclosure relates to a method and device for measuring the health of a multicell automotive battery, in particular a method and device for measuring the internal resistance of a multicell automotive battery.

The present disclosure stresses how the capacity of a multicell battery is defined by its weakest cell, thus the capacity of the battery is given by the capacity of the most degraded cell. It is a commonly known fact that the internal resistance increases as the cell degrades, and this results in a lower cell capacity as well as a lower C-rate. Thus, a practical and effective method and device for measuring the internal resistance of a multicell automotive battery could be used for estimating the health, capacity and C-rate of said battery.

It is disclosed a method for measuring the internal resistance of a multicell automotive battery comprising a plurality of battery cells in series, when in operation of providing electrical current under electrical voltage, comprising the steps of:
scanning the plurality of battery cells for measuring their respective voltage until the battery current has been stable for a full cell scan with a current value;
recording said current value and the scanned battery cell voltages;
using the recorded current value and battery cell voltages to calculate the internal resistance of each battery cell.

An embodiment further comprises the steps of:
scanning the plurality of battery cells for measuring their respective voltage until the battery current has been stable for a full cell scan with a second current value which is different from said first current value;
recording said second current value and the second scanned battery cell voltages; using the recorded first current value, first battery cell voltages, second current value, and second battery cell voltages to calculate the internal resistance of each battery cell.

In an embodiment, the first current value and second current value are selected from predetermined C-rate fractions of the multicell automotive battery.

In an embodiment, the first current value and second current value are selected from 25%, 50%, 75% and 100% fractions of the C-rate of the multicell automotive battery.

In an embodiment, the second current value is defined as being different from the first current value if they differ by more than 250 mA, in particular by more than 500 mA, further in particular by more than 100 mA.

In an embodiment, the battery current is defined as being stable as being within a predetermined interval of a minimum and a maximum current value.

In an embodiment, the battery current is defined as being stable as being within a predetermined interval of a predetermined maximum current variation.

In an embodiment, the battery current is defined as being stable as being within a predetermined interval of 10% current variation, further in particular 5%, 2%, or 1% of current variation.

In an embodiment, the battery current is defined as being stable as being within a predetermined interval within 1 mA variation.

It is also disclosed a method for estimating the health of the multicell automotive battery from the measured internal resistance of each cell of said multicell automotive battery.

It is also disclosed a method for estimating the multicell automotive battery capacity for estimating the multicell automotive battery capacity or C-rate from the measured internal resistance of each cell of said multicell automotive batteryof each cell of said multicell automotive battery.

It is also disclosed a non-transitory storage media including program instructions for implementing a method for measuring the internal resistance of a multicell automotive battery comprising a plurality of battery cells in series, when in operation of providing electrical current under electrical voltage, the program instructions including instructions executable to carry out the method of any of the described embodiments.

It is also disclosed a device for measuring the internal resistance of a multicell automotive battery comprising a plurality of battery cells in series, when in operation of providing electrical current under electrical voltage, comprising an electronic data processor configured for carrying out the method of any of the described embodiments.

The device for measuring the internal resistance of a multicell automotive battery may be a vehicle on-board device or embedded device.

### BRIEF DESCRIPTION OF THE DRAWINGS

The following figures provide preferred embodiments for illustrating the disclosure and should not be seen as limiting the scope of invention.

FIG. 1: Schematic representation of an embodiment of voltage drop in current function of 8 cells.

FIG. 2: Schematic representation of an embodiment of internal resistance variation function of discharge current in 8 cells.

FIG. 3: Schematic representation of an embodiment of average internal resistance of 8 cells.

FIG. 4: Schematic representation of an embodiment of voltage drop in current function of a battery with 4 cells.

FIG. 5: Schematic representation of an embodiment of internal resistance variation function of discharge current in battery with 4 cells.

FIG. 6: Schematic representation of an embodiment of average internal resistance of a battery with 4 cells.

FIG. 7: Schematic representation of an embodiment of voltage drop in current function of a battery with 4 cells.

FIG. 8: Schematic representation of an embodiment of internal resistance variation function of discharge current in 4 cells.

FIG. 9: Schematic representation of an embodiment of average internal resistance of 4 cells.

FIG. 10: Schematic representation of a cell equivalent circuit of an embodiment according to the disclosure.

### DETAILED DESCRIPTION

The present disclosure relates to a method and device for measuring the health of a multicell automotive battery, in particular a method and device for measuring the internal resistance of a multicell automotive battery. The following pertains to embodiments of the disclosed method and device.

While vehicles are moving current varies, but its value can stay unaltered for some periods of time, benefiting of that periods over, for example, 3 seconds we take a log of cells voltage, and wait for another stable period with a different current value and get another log of cells voltage.

Multicell automotive batteries comprise a very large number of battery cells, such that interrogating (or scanning, or logging) of the voltage all said cells may take quite a substantial amount of time. By waiting until battery current is stable during a full scan of all the battery cells, it is possible to obtain a precise current and voltage measurement for all battery cells.

With two logs it is possible to calculate internal resistance in order to collect the battery cells state. The following formula can then be used:

internal Resistance=(Voltage1−Voltage2(V))/(Current2−Current1(A)) (Eq. 1)

The different approach consists in measuring all the cells voltage while the current is kept constant at some value, that exact value is not so important as we keep calculating to all constant current periods found stable for a period of, for example, at least 3 seconds while vehicles are in movement, which permits not just to monitor cells without removing the battery from the car, but to monitor them regardless the need of stopping operation in addition to the possibility of doing that in real time without direct action on the charge/discharge rates, just by using normal driving circuits. The following pertains to results of embodiments of the disclosed method and device.

The following pertains to Embodiment 1-8 cells (18650 1000 mAh).

There is a proportional correlation between voltage (X-axis) and current (Y-axis), that is presented on the attached plot of 8 unitary cell batteries.

TABLE 1
Voltage drop in current function of 8 cells.

| Current (A) | Cell1 (V) | Cell2 (V) | Cell3 (V) | Cell4 (V) | Cell5 (V) | Cell6 (V) | Cell7 (V) | Cell8 (V) |
|---|---|---|---|---|---|---|---|---|
| 0 | 3.969 | 4.029 | 3.999 | 3.990 | 3.991 | 4.130 | 4.079 | 4.131 |
| 0.25 | 3.840 | 3.990 | 3.880 | 3.839 | 3.961 | 4.100 | 4.010 | 4.079 |
| 0.5 | 3.701 | 3.941 | 3.760 | 3.699 | 3.929 | 4.060 | 3.940 | 4.030 |
| 0.75 | 3.569 | 3.901 | 3.651 | 3.581 | 3.900 | 4.020 | 3.880 | 3.981 |
| 1 | 3.441 | 3.860 | 3.530 | 3.460 | 3.860 | 3.989 | 3.809 | 3.930 |
| 1.25 | 3.311 | 3.810 | 3.409 | 3.329 | 3.829 | 3.951 | 3.739 | 3.881 |
| 1.5 | 3.170 | 3.760 | 3.261 | 3.190 | 3.790 | 3.910 | 3.661 | 3.829 |
| 1.75 | 3.059 | 3.709 | 3.119 | 3.060 | 3.750 | 3.869 | 3.570 | 3.769 |
| 2 | 2.950 | 3.669 | 2.971 | 2.850 | 3.719 | 3.831 | 3.399 | 3.701 |

Constant discharge current (X-axis mA) was applied to the cells of 0 mA, 250 mA, 500 mA, 750 mA, 1000 mA, 1250 mA, 1500 mA, 1750 mA and 2000 mA, and the sample was taken registering the voltage (y-axis in Volts) for each current value to obtain the pattern above. As we can see, cell 6 is the one in better shape, there was a minimal variation of the voltage during the trial.

TABLE 2
Internal resistance variation function of discharge current in 8 cells.

| Current (A) | Cell1 (V) | Cell2 (V) | Cell3 (V) | Cell4 (V) | Cell5 (V) | Cell6 (V) | Cell7 (V) | Cell8 (V) |
|---|---|---|---|---|---|---|---|---|
| 0.25 | 0.519 | 0.158 | 0.477 | 0.602 | 0.120 | 0.118 | 0.275 | 0.206 |
| 0.5 | 0.555 | 0.195 | 0.479 | 0.562 | 0.127 | 0.161 | 0.282 | 0.196 |
| 0.75 | 0.527 | 0.161 | 0.438 | 0.473 | 0.119 | 0.158 | 0.238 | 0.199 |
| 1 | 0.513 | 0.164 | 0.484 | 0.484 | 0.157 | 0.125 | 0.285 | 0.203 |
| 1.25 | 0.521 | 0.197 | 0.482 | 0.522 | 0.125 | 0.153 | 0.280 | 0.196 |
| 1.5 | 0.560 | 0.202 | 0.593 | 0.556 | 0.157 | 0.164 | 0.314 | 0.207 |
| 1.75 | 0.445 | 0.202 | 0.567 | 0.520 | 0.160 | 0.163 | 0.364 | 0.239 |
| 2 | 0.437 | 0.160 | 0.593 | 0.840 | 0.123 | 0.153 | 0.683 | 0.276 |

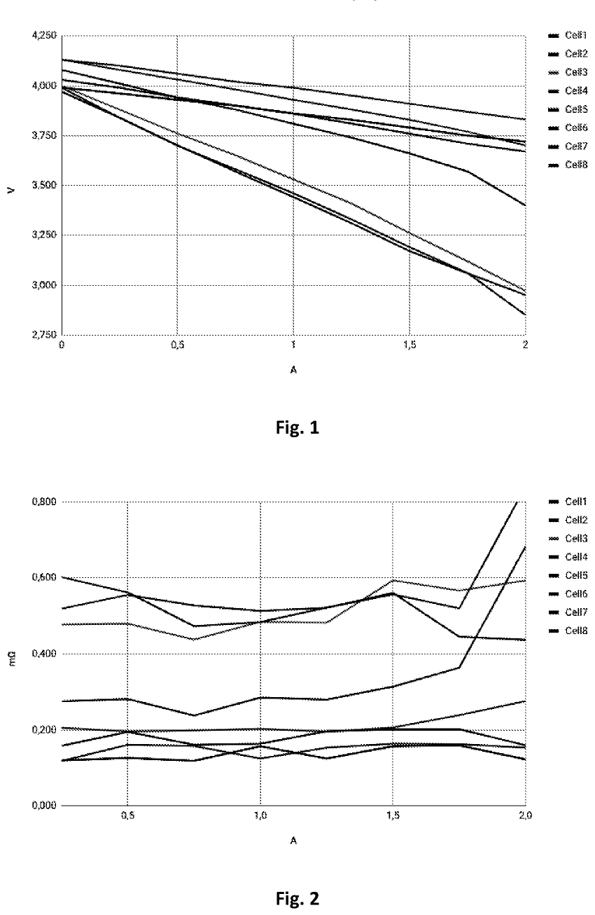

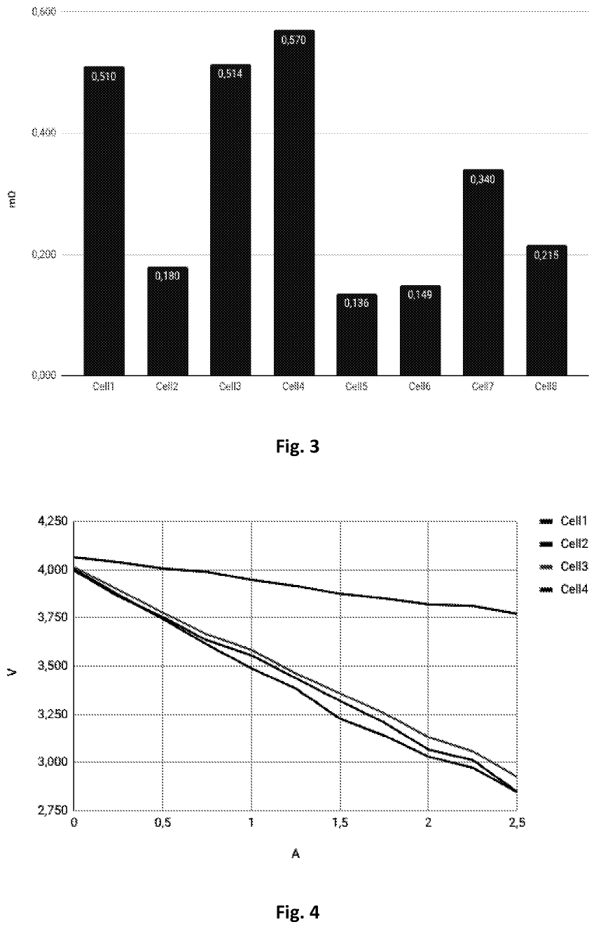

Internal resistance measurements are represented above. The values at FIG. 2 plot were calculated applying (1) to the values obtained experimentally FIG. 1.

As we can see above, cells 4 and 7 have high internal resistance and for high discharge current values its internal resistance limits the output power, presenting inaccurate measurements.

The X-axis represents the current (mA) values, and y-axis represents internal resistance (mΩ). As said before it is visible that the healthier cells are numbers 5 and 6, followed by cell 2 and 8, having the lower internal resistance and minor variation. Other cells have a higher internal resistance due to cell ageing, misapplications, or even both combined, decreasing the battery output power.

The following pertains to Embodiment 2—Battery 4S1P (18650 1000 mAh).

TABLE 3
Voltage drop in current function of a battery with 4 cells.

| Current (A) | Cell1 (V) | Cell2 (V) | Cell3 (V) | Cell4 (V) |
|---|---|---|---|---|
| 0 | 4.002 | 4.064 | 4.012 | 3.994 |
| 0.25 | 3.871 | 4.038 | 3.896 | 3.862 |
| 0.5 | 3.745 | 4.006 | 3.778 | 3.755 |
| 0.75 | 3.612 | 3.989 | 3.664 | 3.634 |
| 1 | 3.489 | 3.948 | 3.584 | 3.556 |
| 1.25 | 3.384 | 3.916 | 3.462 | 3.438 |
| 1.5 | 3.227 | 3.876 | 3.359 | 3.319 |
| 1.75 | 3.140 | 3.851 | 3.256 | 3.208 |
| 2 | 3.030 | 3.820 | 3.132 | 3.067 |
| 2.25 | 2.972 | 3.812 | 3.058 | 3.012 |
| 2.5 | 2.846 | 3.771 | 2.925 | 2.848 |

A second trial was done using a battery composed by a series of 4 cells. The same step values of discharge current (X-axis mA) was applied to series of 4 cells of 0 mA, 250 mA, 500 mA, 750 mA, 1000 mA, 1250 mA, 1500 mA, 1750 mA, 2000 mA, 2250 mA and 2500 mA, and the sample was taken registering the voltage (y-axis in Volts) for each current value to obtain the pattern above. As we can see, cell 2 is the one in better shape presenting the lowest voltage variation of the voltage during the trial.

TABLE 4
Internal resistance variation function of
discharge current in battery with 4 cells.

| Current (A) | Cell1 (V) | Cell2 (V) | Cell3 (V) | Cell4 (V) |
|---|---|---|---|---|
| 0.25 | 0.524 | 0.103 | 0.462 | 0.531 |
| 0.5 | 0.504 | 0.128 | 0.473 | 0.429 |
| 0.75 | 0.531 | 0.068 | 0.455 | 0.483 |
| 1 | 0.494 | 0.167 | 0.320 | 0.310 |
| 1.25 | 0.418 | 0.127 | 0.488 | 0.472 |
| 1.5 | 0.627 | 0.160 | 0.413 | 0.475 |
| 1.75 | 0.350 | 0.098 | 0.414 | 0.446 |
| 2 | 0.437 | 0.125 | 0.496 | 0.562 |
| 2.25 | 0.232 | 0.033 | 0.295 | 0.220 |
| 2.5 | 0.504 | 0.162 | 0.530 | 0.658 |

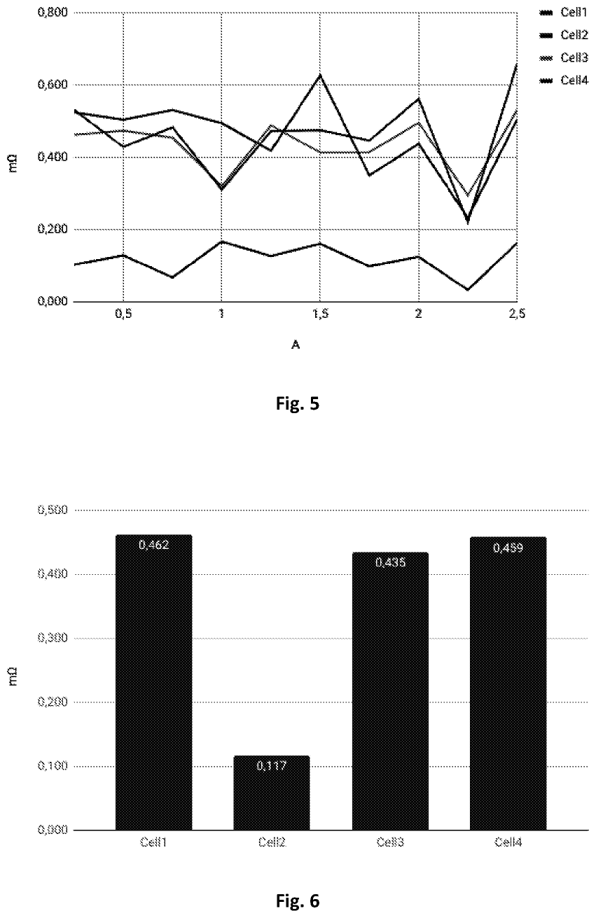

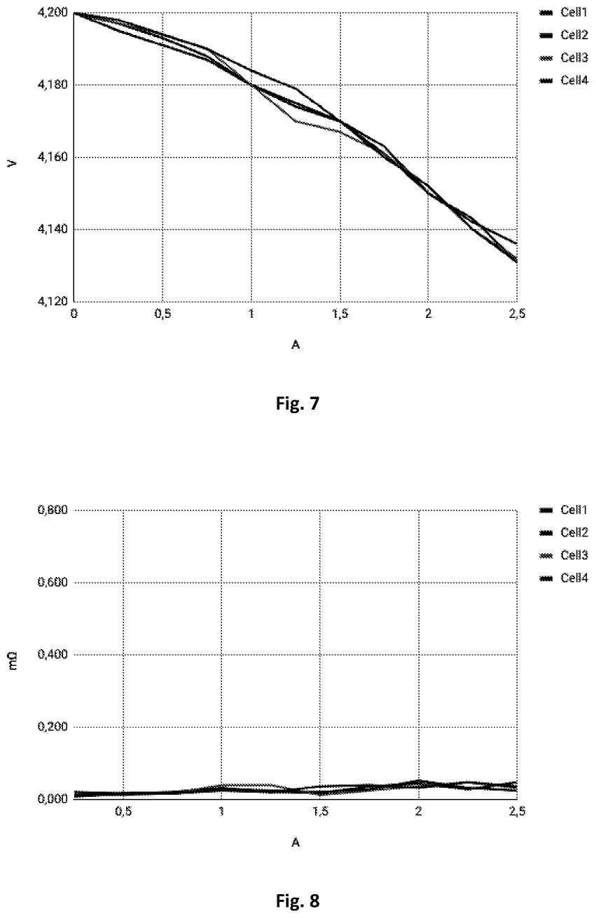

The chart in FIG. 5 shows the internal resistance obtained from the voltage/current plot represented at FIG. 4. The average internal resistance of the battery is represented at bar graph depicted at FIG. 6.

The X-axis represents the current (mA) values, and y-axis represents internal resistance (mΩ). As said before on trial 1, it is visible that the cell number 2 presents lower internal resistance, also having lower variation.

The following pertains to Embodiment 3—Battery 4S1P (LiPo 1300 mAh).

On this trial, a newer battery was used, having higher C-Rate. It is possible to observe that the cells are at the same voltage condition and health.

TABLE 5
Cell voltage function of discharge current.

| Current (A) | Cell1 (V) | Cell2 (V) | Cell3 (V) | Cell4 (V) |
|---|---|---|---|---|
| 0 | 4.200 | 4.200 | 4.200 | 4.200 |
| 0.25 | 4.195 | 4.197 | 4.197 | 4.198 |
| 0.5 | 4.191 | 4.193 | 4.194 | 4.194 |
| 0.75 | 4.187 | 4.188 | 4.190 | 4.190 |
| 1 | 4.180 | 4.180 | 4.180 | 4.184 |
| 1.25 | 4.174 | 4.175 | 4.170 | 4.179 |
| 1.5 | 4.170 | 4.170 | 4.167 | 4.170 |
| 1.75 | 4.161 | 4.163 | 4.161 | 4.160 |
| 2 | 4.150 | 4.150 | 4.152 | 4.152 |
| 2.25 | 4.143 | 4.142 | 4.140 | 4.140 |
| 2.5 | 4.131 | 4.136 | 4.132 | 4.131 |

The same step values of discharge current (X-axis mA) was applied to series of 4 cells of 0 mA, 250 mA, 500 mA, 750 mA, 1000 mA, 1250 mA, 1500 mA, 1750 mA, 2000 mA, 2250 mA and 2500 mA, and the sample was taken registering the voltage (y-axis in Volts) for each current value to obtain the pattern above.

TABLE 6
Internal resistance variation function of discharge current in 4 cells.

| Current (A) | Cell1 (V) | Cell2 (V) | Cell3 (V) | Cell4 (V) |
|---|---|---|---|---|
| 0.25 | 0.020 | 0.012 | 0.012 | 0.008 |
| 0.5 | 0.016 | 0.016 | 0.012 | 0.016 |
| 0.75 | 0.016 | 0.020 | 0.016 | 0.016 |
| 1 | 0.028 | 0.032 | 0.040 | 0.024 |
| 1.25 | 0.024 | 0.020 | 0.040 | 0.020 |
| 1.5 | 0.016 | 0.020 | 0.012 | 0.036 |
| 1.75 | 0.036 | 0.028 | 0.024 | 0.040 |
| 2 | 0.044 | 0.052 | 0.036 | 0.032 |
| 2.25 | 0.028 | 0.032 | 0.048 | 0.048 |
| 2.5 | 0.048 | 0.024 | 0.032 | 0.036 |

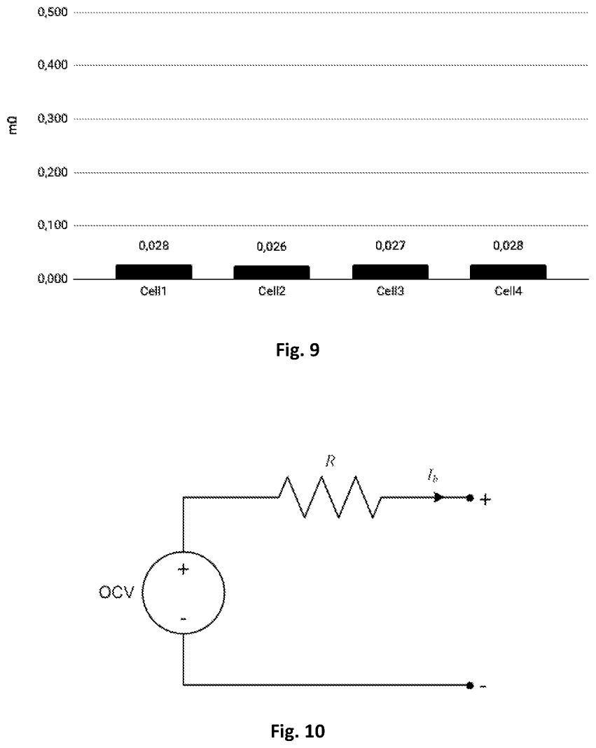

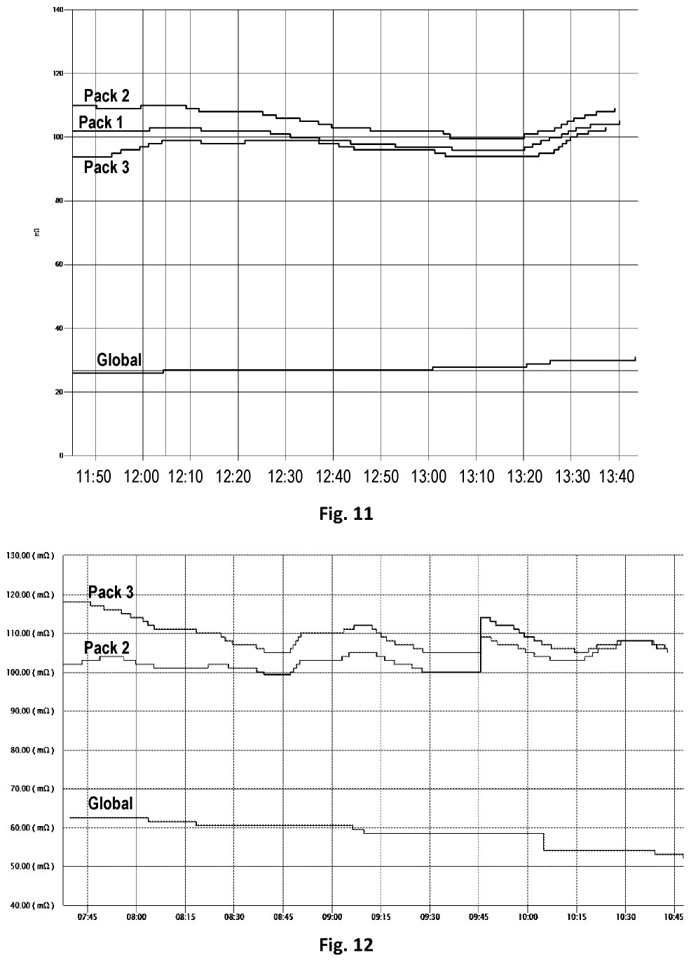

The chart in FIG. 8 shows the internal resistance obtained from the voltage/current plot represented at FIG. 9. Comparing to the trial 2, this battery presents a lower internal resistance due to its higher C-rate.

C-rate is an indicator used by battery providers to scale the charge and discharge current of a battery. For a given capacity, C-rate is a measure that indicates at what current a battery may be charged and/or discharged to reach its defined capacity. It is advantageous because to some extent, C-rate is the limiting factor for maximum power that may be extracted out of a battery pack. Estimation of C-rate is depicted after the internal resistance estimation. According to Ohm's law, the current in a circuit depends on its voltage and resistance. On an electrochemical accumulator the same formula is still valid, where the output voltage drop will increase as the current rises. At very high current values, the voltage will drop to values where protection systems will enter to avoid over discharge of the batteries. The C-rate can be determined as the maximum current a battery is capable is supplying safely expressed in relation to its capacity in Ampere per hour. For example, if a battery is marked as a 200 Ah unit and its C-rate is 2 C, then the maximum working current of that battery will be 2×200=400 A.

The application of the present disclosure to vehicular batteries can be verified on FIG. 11 where the internal resistance of 3 different battery packs used to supply power to a heavy-duty passenger vehicle were analysed. The battery packs are connected in parallel and their internal resistance was monitored according to previously detailed process. The equivalent resistance of the 3 battery packs connected in parallel is similar to the calculated overall resistance of the compete pack. On FIG. 12 the same vehicle has one of its battery packs disconnected from the group, the calculated internal resistance of each pack remains stable according to previous measures but resulting on a higher equivalent internal resistance. It was observed that the measured value for the complete battery pack followed this variation.

It is to be appreciated that certain embodiments of the disclosure as described herein may be incorporated as code (e.g., a software algorithm or program) residing in firmware and/or on computer useable medium having control logic for enabling execution on a computer system having a computer processor, such as any of the servers described herein. Such a computer system typically includes memory storage configured to provide output from execution of the code which configures a processor in accordance with the execution. The code can be arranged as firmware or software, and can be organized as a set of modules, including the various modules and algorithms described herein, such as discrete code modules, function calls, procedure calls or objects in an object-oriented programming environment. If implemented using modules, the code can comprise a single module or a plurality of modules that operate in cooperation with one another to configure the machine in which it is executed to perform the associated functions, as described herein.

The disclosure should not be seen in any way restricted to the embodiments described and a person with ordinary skill in the art will foresee many possibilities to modifications thereof. The above described embodiments are combinable. The following claims further set out particular embodiments of the disclosure.

1. A method for measuring the internal resistance of a multicell automotive battery comprising a plurality of battery cells in series, when in operation of providing electrical current under electrical voltage, comprising the steps of:
scanning the plurality of battery cells for measuring their respective voltage until the battery current has been stable for a full cell scan with a current value;
recording said current value and the scanned battery cell voltages; and
using the recorded current value and battery cell voltages to calculate the internal resistance of each battery cell.

2. The method according to claim 1, further comprising the steps of:
scanning the plurality of battery cells for measuring their respective voltage until the battery current has been stable for a full cell scan with a second current value which is different from said first current value;
recording said second current value and the second scanned battery cell voltages; and
using the recorded first current value, first battery cell voltages, second current value, and second battery cell voltages to calculate the internal resistance of each battery cell.

3. The method according to claim 1, wherein the first current value and second current value are selected from predetermined C-rate fractions of the multicell automotive battery.

4. The method according to claim 1, wherein the first current value and second current value are selected from among 25%, 50%, 75% and 100% fractions of the C-rate of the multicell automotive battery.

5. The method according to claim 2, wherein the second current value is defined as being different from the first current value if they differ by more than 250 mA.

6. The method according to claim 1, wherein the battery current is defined as being stable as being within a predetermined interval of a minimum and a maximum current value.

7. The method according to claim 1, claims wherein the battery current is defined as being stable as being within a predetermined interval of a predetermined maximum current variation.

8. Method according to claim 7, wherein the battery current is defined as being stable as being within a predetermined interval of 10% current variation.

9. The method according to claim 6, wherein the battery current is defined as being stable as being within a predetermined interval within 1 mA variation.

10. The method according to claim 1, for estimating the health of the multicell automotive battery from the measured internal resistance of each cell of said multicell automotive battery.

11. The method according to claim 10, for estimating the multicell automotive battery capacity or C-rate from the measured internal resistance of each cell of said multicell automotive battery.

12. The method according to claim 1, further comprising the step of calculating an updated C-rate of the multicell automotive battery from the measured internal resistance of each cell.

13. A non-transitory storage media including program instructions for implementing a method for measuring the internal resistance of a multicell automotive battery comprising a plurality of battery cells in series, when in operation of providing electrical current under electrical voltage, the program instructions including instructions executable to carry out the method of claim 1.

14. A device for measuring the internal resistance of a multicell automotive battery comprising a plurality of battery cells in series, when in operation of providing electrical current under electrical voltage, comprising an electronic data processor configured for carrying out the method of claim 1.

15. the device for measuring the internal resistance of a multicell automotive battery according to claim 14, wherein the device is a vehicle on-board or vehicle embedded device.
